(19) United States
(12) Patent Application Publication
(10) Pub. No.: US 2015/0380905 A1
(43) Pub. Date: Dec. 31, 2015

(54) PHOTONIC CIRCUIT DEVICE WITH REDUCED LOSSES CAUSED BY ELECTRICAL CONTACT PADS

(71) Applicant: International Business Machines Corporation, Armonk, NY (US)

(72) Inventor: Jens Hofrichter, Gattikon (CH)

(21) Appl. No.: 14/750,039

(22) Filed: Jun. 25, 2015

(30) Foreign Application Priority Data
Jun. 26, 2014 (GB) 1411359.1

(51) Int. Cl. H01S 5/32; H01S 5/30; H01S 5/20; H01S 5/323

(52) U.S. Cl. CPC H01S 5/32; H01S 5/3235; H01S 5/3009; H01S 5/2009

(57) ABSTRACT

A photonic circuit device can include a light-generating structure and at least two electrical contact pads. The light-generating structure can include: an n-doped semiconductor layer; a p-doped semiconductor layer; and an active gain section. The active gain section can include layers stacked along a stacking direction; can be arranged between the semiconductor layers; and can be coupled in the photonic circuit. The electrical contact pads can include an n-contact electric pad and a p-contact electric pad, in electrical contact with the n-doped semiconductor layer and the p-doped semiconductor layer, respectively. One of the pads can be in direct contact with the light-generating structure. In embodiments, the ratio of a width of the one of the electrical contact pads to the width of the active gain section can be between 1.35 and 3.85 measured in a direction that is orthogonal to each of the stacking direction and the propagation direction.

### CROSS-REFERENCE TO RELATED APPLICATION

This application is related to and claims the benefit of United Kingdom Patent Application No. 1411359.1, filed Jun. 26, 2014, which is incorporated by reference herein for all purposes.

### BACKGROUND

The present disclosure relates in general to the field of photonic circuit devices and techniques to reduce losses caused by electrical contact pads of such devices. Embodiments more particularly concern Laser devices fabricated between the front end and the back end of line of a Complementary metal-oxide-semiconductor (CMOS) process. However, aspects of the present disclosure can be applied to other technologies, like, e.g., bulk InP, bulk GaAs, etc.

To meet the requirements of future computing systems, high speed and energy efficient alternatives to on-chip electrical interconnects are needed. Integrated optics, in particular silicon photonics, meets these requirements. Integrated optical interconnects with low power consumption and high optical output power are required in future computing systems.

The current state-of-the-art resorts to III-V based transceivers, which are made of bulk III-V materials, such as InP for instance. However, as these material systems have a low index contrast between the waveguiding layers and the substrate, the devices are large and thus power hungry. Instead, by integrating high-index contrast III-V based lasers with silicon photonics, much more compact devices can be fabricated. As the devices become substantially smaller, placing the electrical contacts becomes challenging. In particular, if high-speed operation is targeted, placing the contacts such as to achieve low parasitics in conjunction with low access resistance is key.

In state-of-the-art devices, either a bulk InP material offering only limited index contrast is used, or more recently, III-V material is hybrid (heterogeneously) integrated with silicon photonics. In the latter case, as in bulk InP technology, thick lowly-doped epitaxial layer stacks are typically used in order to overcome the high losses of the p-doped regions and the metal interfacing the p-contact.

### SUMMARY

According to embodiments of the present disclosure, a photonic circuit device can include a light-generating structure and at least two electrical contact pads. The light-generating structure can include: an n-doped semiconductor layer; a p-doped semiconductor layer; and an active gain section. The active gain section can include layers stacked along a stacking direction; can be arranged between the n-doped semiconductor layer and the p-doped semiconductor layer; and can be coupled in the photonic circuit device for generating light propagating along a given propagation direction. The at least two electrical contact pads can include an n-contact electric pad and a p-contact electric pad, in electrical contact with the n-doped semiconductor layer and the p-doped semiconductor layer, respectively. One of the electrical contact pads can be in direct contact with the light-generating structure. In embodiments, the ratio of a width of the one of the electrical contact pads to the width of the active gain section can be between 1.35 and 3.85 measured in a direction that is orthogonal to each of the stacking direction and the given propagation direction.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a 2D cross-sectional view of a simplified representation of a device according to embodiments.

FIG. 2 is a 3D view of a simplified representation of a device according to embodiments.

FIG. 3 is a plot representing the variation of the quality factor with respect to the width of the p-contact electrical contact pad (the width of the active gain section being assumed to be 400 nm in this example).

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

The present disclosure relates in general to the field of photonic circuit devices and techniques to reduce losses caused by electrical contact pads of such devices. Embodiments more particularly concern Laser devices fabricated between the front end and the back end of line of a Complementary metal-oxide-semiconductor (CMOS) process. However, aspects of the present disclosure can be applied to other technologies, like, e.g., bulk InP, bulk GaAs, etc. While the present disclosure is not necessarily limited to such applications, various aspects of the disclosure can be appreciated through a discussion of various examples using this context.

In embodiments, said ratio η is between 1.80 and 2.70. In embodiments, said one of the electrical contact pads can further have one or more of the following features: it is stacked onto the light-generating structure, along the stacking direction; it is centered with respect to the light-generating structure; it is cantilevered overhang on the light-generating structure; and it is in direct contact with the light-generating structure is the p-contact electric pad.

In embodiments, the above device further includes two separate confinement heterostructure layers on each side of the active gain section, e.g., along the stacking direction, and between the n-doped and p-doped semiconductor layers. In preferred embodiments, the width of the active gain section is less than 10 000 nm and, preferably, is larger than 100 nm, and more preferably is larger than 200 nm. Preferably, the width of the active gain section is less than 1 000 nm. In embodiments, the above device further includes a substrate, preferably a Silicon substrate, supporting the light-generating structure, which substrate otherwise includes a photonic circuit.

Advantageously, in embodiments, another one of the electrical contact pads, preferably the n-contact pad, is not stacked with the light-generating structure and is laterally offset from the light-generating structure, in the direction in which said widths are measured.

In embodiments, the active gain section has a ring shape. Preferably, the active gain section includes a stack of InAlGaAs layers of alternating thicknesses, the latter preferably being, each, between 15.0 and 2.0 nm, and wherein each of the n-doped and p-doped semiconductor layers includes InP, and wherein, more preferably, the light-generating structure further includes two separate confinement heterostructure layers on each side of the active gain section, and between the n-doped and p-doped semiconductor layers, which confinement heterostructure layers include, each, InAlGaAs (e.g., for operation at 1300 nm).

In variants of the present disclosure, the active gain section can include a stack of alternating InAsP and InGaAsP layers of alternating thicknesses, and the confinement heterostructure layers can include, each, InGaAsP, e.g., for operation at 1550 nm.

Finally, the present invention, in embodiments, can further be embodied as a CMOS device, including any one of the above device, arranged between a front end of line and a back end of line of the CMOS device.

Devices embodying the present invention and fabrication methods thereof will now be described, by way of non-limiting examples, and in reference to the accompanying drawings. Technical features depicted in the drawings are not necessarily to scale.

The following description is structured as follows. First, general embodiments and high-level variants are described (sect. 1). The next section addresses more specific embodiments and technical implementation details (sect. 2).

### 1. General Embodiments and High-Level Variants

As noted in introduction, thick epitaxial layer stacks are typically used to overcome the abrupt losses of the p-contact and the metal interfacing the p-contact. It can, however, be realized that this results in slow device speed and moreover hinders the exploitation of advantages of silicon photonics (small device size, planar integration with electronics, high operation speed and low power operation).

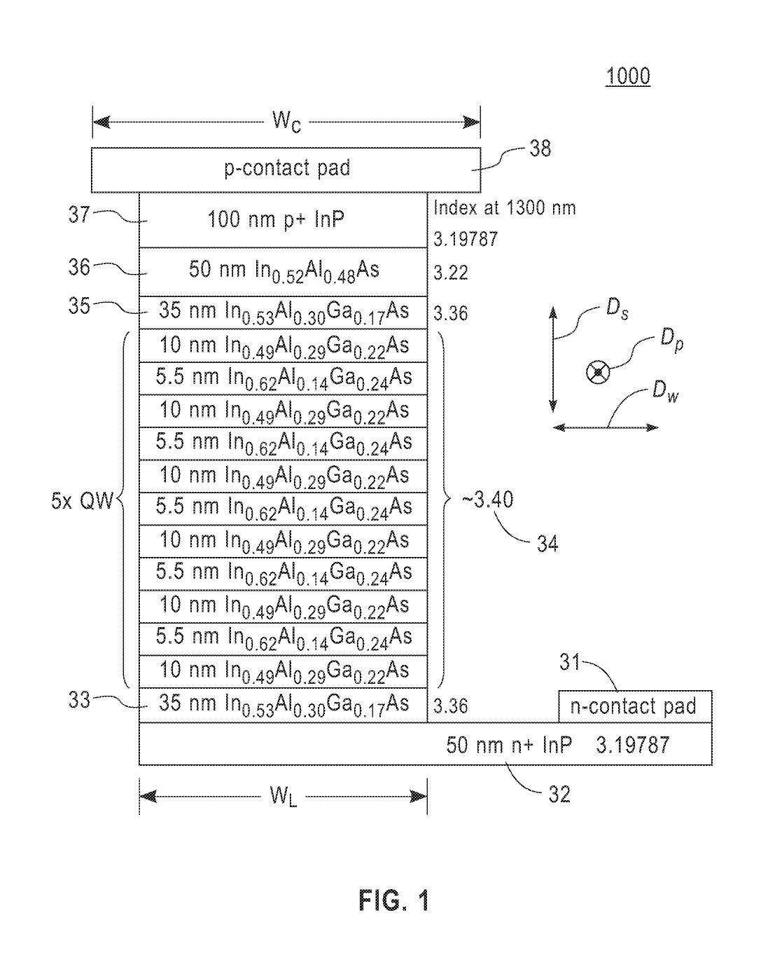

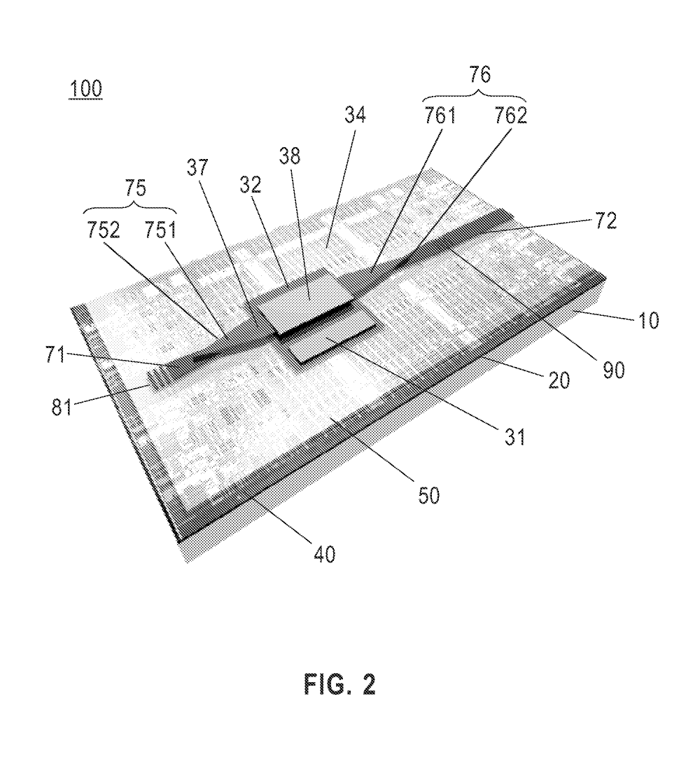

To overcome such issues, some embodiments can revolve around a new contacting scheme. This can open new ways of electrically connecting a light-generating structure such as a laser to other photonic components, and also to the driving electronic residing on a same chip or die. The proposed embodiments of the invention can circumvent drawbacks discussed earlier and can be well suited for the implementation of laser devices or optical amplifiers for high-speed operation. In reference to FIGS. 1 and 2, an embodiment of the invention is first described, which concerns a photonic circuit device 100. Basically, the latter includes: a light-generating structure 32-37, at least two electrical contact pads 31, 38. The light-generating structure 32-37 includes: a n-doped semiconductor layer 32; a p-doped semiconductor layer 37; and an active gain section 34. For more related information on light-generating structures, see for instance J. Hofrichter, T. Morf, A. La Porta, O. Raz, H. J. S. Dorren, and B. J. Offrein, Optics Express, Vol. 20, No. 26, pp. B365-B370, 2012, or A. W. Fang, H. Park, O. Cohen, R. Jones, M. J. Paniccia, and J. E. Bowers, Optics Express, 14, 9203-9210, Oct. 2, 2006.

In embodiments, the active gain section 34 includes layers stacked along a stacking direction Dₛ, as seen in FIG. 1. This active gain section 34 is arranged between the n-doped semiconductor layer 32 and the p-doped semiconductor layer 37. Generally, this section 34 is adequately coupled in the device for generating light. The generated light propagate along a given propagation direction Dₚ. Said propagation direction Dₚ should be understood as an average propagation direction of light, which is sometimes called “optical axis”, especially in the old literature.

The electrical contact pads can notably serve to enable electrical pumping of the light-generating structure. They include an n-contact electric pad 31 and a p-contact electric pad 38, which are in electrical contact with the n-doped semiconductor layer 32 and the p-doped semiconductor layer 37, respectively. As seen in FIG. 1, one 38 of the electrical contact pads, at least, is in direct contact with the light-generating structure 32-37. This electrical contact pad is hereafter referred to as the “top” electrical contact pad, for the sake of simplicity (and without prejudice).

Remarkably, in embodiments, there is a discrepancy between the widths of the top electrical contact pad 38 and the width of the active gain section 34. Namely, and as the present inventor has realized, it can be advantageous to use structures wherein the ratio η of the width W_{c} of the top electrical contact pad 38 to the width W_{L} of the active gain section 34 is between 1.35 and 3.85. This can be for reasons that are explained below. Each of said widths W_{c} and W_{L} is measured in a same direction D_{w}, which is orthogonal to each of the stacking direction Dₛ and said given propagation direction Dₚ.

As documented herein, the present inventor has realized that providing such a ratio η can allow, in some embodiments, substantial reduction in the internal optical losses in the device and, correlatively, to reduce losses caused by the electrical contact pads. Such losses can be even more substantially reduced if the ratio η is between 1.80 and 2.70 (that is, larger than or equal to 2.0±10% and less than or equal to 3.0±10%).

This, in turn, can make it possible to design structures where the contact pads are placed closer to the light-generating structure, such that one is able to fabricate thinner (or shallower) structures. Whereas state-of-the-art laser devices resort to a thick, lowly doped, and thus little absorbing p-region, whose thickness typically is of 1 to 2 micrometers, here, in embodiments, this layer can be simply omitted such that the total thickness of the active gain section can be below 1 micrometer. As a result, this can enable the fabrication of light-generating structures (e.g., lasers) between the front end and the back end of line of a CMOS process. The above concept can nevertheless, in embodiments, be advantageously implemented independently from CMOS processes, for example in bulk-InP photonic integration technologies.

The advantageous properties that can result from the above ratio can furthermore be, in embodiments, largely independent from the contact material, as tests conducted with several metal types (e.g., W, Ti, Ni, etc.) have confirmed. In addition, in embodiments, the present width ratios result in that the alignment of the contact pads can not, in some embodiments, be critical: substantial offsets are allowed and can even be beneficial in some cases. Finally, in embodiments, no additional lithography/patterning steps are needed, compared to the usual fabrication methods used for fabricating electrical contact pads (metal lift-off or metal dry etching). In particular, the present concept does not, in embodiments, require micropatterning steps of the metal contact.

First, in embodiments, only one 38 of the contact pads has to verify the above condition (with respect of the ratio η), as the width of the other pad 31 is manifestly not critical in embodiments, according to tests performed so far. It can even be irrelevant to the desired property. Now, in embodiments, this other pad 31 can nevertheless be stacked with the active gain section 34 as well and exhibit a width ratio therewith. For instance, this other pad 31 could be arranged similarly as the first pad 38 but underneath the gain stack 34. This, however, could be much more difficult to fabricate because it could be difficult to bond it on top of a suitable substrate (e.g., a Si substrate) and below an n-doped layer (e.g., an InP n-doped layer).

Second, the top electrical contact pad 38, i.e., the pad in direct contact with the light-generating structure is preferably the p-contact electric pad. The reason is that the n-contact at the bottom is usually less absorbing than the p-contact pad, such that it is preferred to have the p-contact on top, i.e., as far away as possible from the underlying substrate 10 (on which Si photonics or other electronics can be provided). Now, as the skilled person can realize, in some particular cases (e.g., in tunnel junctions), it can be preferably to have the n-contact pad on top, that is, in direct contact with the light-generating structure. In that respect, note that the n-contact pad used to be referred to as the cathode, and the p-contact pad as the anode, in the old literature. The electrical contact pads are generally made of metal or metallic alloys, as known per se.

In this respect, one notes that the p-pad typically has a negative refractive index at the desired working wavelength (as generally known in the art), while the n-pad does not, in embodiments, need to have a negative refractive index, unless it is arranged underneath the gain stack. For that reason, in preferred embodiments of the device 100 of any one of claims 1 to 10, this other contact pad 31, which preferably is the n-contact pad, is not stacked with the light-generating structure 32-37. On the contrary, it is preferably laterally offset from the light-generating structure, in the direction D_{w} in which the widths are measured.

The features described above (contact pads and active gain section) are typically arranged on a substrate 10, which shall preferably be provided with a photonic circuit thereon (though variants can involve electronics, as said above). In embodiments where the other contact pad 31 is laterally offset from the light-generating structure, this pad 31 is preferably arranged on top of the same substrate 10 that supports the photonic circuit.

The light-generating structure is a stack of layers (typically an epitaxial stack of layers) involving, e.g., quantum wells or an assembly of quantum dots, or some bulk material, as known per se. For light generation, electrical pumping is preferred, but optical pumping can be contemplated as well.

Beyond the active gain section 34, the n-doped layer 32 and the p-doped layer 37, the light-generating structure can include additional layers, having specific functionalities, as explained below.

The horizontal cross section of the stack of layer (perpendicularly to the stacking direction Dₛ) can typically be rectangular (in waveguide-like implementations), with the successive layers extending in a straight manner along the stacking direction Dₛ. In variants, the stack of layer can also draw a ring, as explained below. The cross section of the gain section 34 that is perpendicular to the average light propagation direction Dₚ is ideally rectangular (although it is rather trapezoidal in practice).

In preferred embodiments, the top electrical contact pad 38 is stacked onto the light-generating structure 32-37, along the stacking direction Dₛ, as depicted in FIG. 1. This provides lower electrical resistance at the contact. In variants, this layer 38 could just touch the light-generating structure, without being stacked onto it. In the latter case, the mean plane of the top electrical contact pad 38 would nonetheless typically extend in the (Dₚ, D_{w}) plane, just like the pad 38 depicted in FIG. 1.

Furthermore, the top electrical contact pad 38 is preferably centered with respect to the light-generating structure 32-37, as illustrated in FIG. 1. This results in further lowering the electrical resistance. In variants, the contact pad 38 could be off-centered, but this mostly results in increased contact resistance and losses. This shall be further discussed below.

As further depicted in FIG. 1, the top electrical contact pad 38 is preferably cantilevered overhang on the light-generating structure. I.e., one or more lateral edges of this pad 38 extend beyond the adjacent (lateral) edges of the light-generating structure (in the direction D_{w}, along which said widths are measured). This can result in changing the mode profiles. In embodiments, the underlying physical mechanism is that the (e.g., metal) pad typically has a negative permittivity, which can force a zero of the electric field at the electrical contact pad/semiconductor boundary. The contacts force a zero of the optical field at the contact interface, thus pushing the optical mode(s) away from the contacts and down, out of the highly doped p-region, thus reducing the overall absorption losses of the resonator or cavity.

Note that ring embodiments can be contemplated, instead of straight (waveguide-like) sections of the light-generating structure. Although a ring shape is not explicitly shown in the appended drawings, the simplified view of FIG. 1 can be regarded as one cross-section of the ring (the other cross-section being not depicted, it would be farther on the left in FIG. 1). A ring profile can enable a low-threshold low power laser, enabling low power operation, at the expense of a less pure spectrum, i.e. a potentially compromised side-mode suppression ratio and less easily controlled absolute wavelength position. In such a case, tests performed by the inventor have shown that the ratio η should preferably be larger than 1.50. Meanwhile, an asymmetric arrangement of the electrical contact pad 38 over the light-generating structure 32-37 (instead of being centered with respect to it) shall generally provide better results, unless the value of the ratio η approaches the specific value of 2.00 (say 2.00±10%), for which a symmetric arrangement is again preferred. But beyond this particular value, asymmetric arrangements were generally found to provide best results for ring arrangements. On the contrary, a symmetric arrangement is always preferred for waveguide-like straight arrangements of the active gain section.

In typical embodiments, the device 10 can further include two separate confinement heterostructure layers 33, 35 on each side of the active gain section 34, and between the n-doped 32 and p-doped 37 semiconductor layers. Such separate confinement heterostructure layers act as barriers, to at least partly prevent charge carriers from travelling through the gain section without recombining, as known per se.

In particularly preferred embodiments, the width WL of the active gain section 34 is less than 10 000 nm. As the skilled person can appreciate, values less than 10 000 nm shall normally allow to prevent a laser mode having a larger diameter than a single mode fiber. Now, to obtain a low-loss single mode waveguide, it is preferred to have W_{L}>100 nm. Yet, providing W_{L}>200 nm can relax fabrication challenges and reduce the scattering losses by sidewall roughness.

Now, in order to have single-mode operation and prevent multi-mode operation, one would rather choose W_{L}<1000 nm. The loss reduction can indeed be substantially more pronounced below 1 000 nm, e.g., in embodiments, the losses were found to drop by two orders of magnitude passing from W_{L}=400 to 600 and by four orders of magnitude when passing from 400 to 1000 nm.

In particularly preferred embodiments, the active gain section 34 includes a stack of InAlGaAs layers of alternating thicknesses. Said thicknesses are preferably, each, between 2.0 and 15.0 nm. As further depicted in FIG. 1, each of the n-doped and p-doped semiconductor layers can for instance include InP.

As said earlier, the light-generating structure 32-37 can further include two separate confinement heterostructure layers 33, 35 (each including InAlGaAs in this example), on each side of the active gain section 34, i.e., between the n-doped and p-doped semiconductor layers 32, 37. The structure can further include an electron blocking layer 36, e.g., an InAlAs layer, to improve the quantum efficiency.

Referring now more specifically to FIG. 2: the device 10 described above typically includes a substrate 10, which preferably is a silicon substrate. In embodiments, the substrate 10 notably supports the light-generating structure and can otherwise include a photonic circuit. This substrate 10 is typically in indirect contact with the n-doped semiconductor layer 32, a dielectric layer being typically provided in-between.

In this respect, devices as described above are preferably included in a CMOS device, where the light-generating structure and electrical pads are arranged between a front end of line and a back end of line of this CMOS device.

The above embodiments have been succinctly described in reference to the accompanying drawings and can accommodate a number of variants. Several combinations of the above features can be contemplated. Examples are given in the next section.

### 2. Specific Embodiments, Technical Implementation Details, Fabrication Process and Results

### 2.1 Specific Embodiments

Specific embodiments are now described in reference to FIG. 2, which depicts an example of a photonic circuit device 100, here designed for optical gain measurement. It should, however, be kept in mind that minor modifications to this circuit (e.g., providing different geometries for the reflectors 81 and 90), would, in embodiments, turn it into a laser device. The circuit shown in FIG. 2 can actually be involved in basic elements of a light-generating structure, which could more generally be embodied as a laser, a light emitting diode (LED), or a superluminescent LED (SLED), etc. In other words, aspects of the present disclosure relate to a low-loss light-generating structure and therefore are not limited to specific embodiments as described below.

The device shown depicted in FIG. 2 includes on-chip gain measurement structures, which can make it possible to easily measure the optical gain measurement of an active gain section 34.

First, the example device 100 includes a substrate 10 with a photonic circuit. The substrate is preferably a silicon wafer but can also be made of Gallium Arsenide (GaAs) or Indium Phosphide (InP). The substrate can notably include: a silicon photonic circuit; a passive InP photonic circuit; or a passive GaAs photonic circuit. It shall hereafter be referred to as a “wafer”, for simplicity, although a typical product can involve a single die, as usual in the art.

The photonic circuit includes one or more waveguides 71, 72, e.g., two waveguides in the example of FIG. 2. Said one or more waveguides 71, 72 are configured such as to define two waveguide portions (at least), which are aligned along a same direction, as apparent in FIG. 2. “Waveguide portion” means a waveguide core portion, as usual in integrated photonics or silicon photonics. Surrounding components, layers or materials, etc., play the role of a cladding. Other components of the photonic circuits are not represented, for conciseness.

The device 100 further includes a light-generating structure 32-37, with an n-doped semiconductor layer 32, a p-doped semiconductor layer 37 and an active gain section 34, just as described in the previous section. The light-generating structure is typically on top of the wafer and coupled in the device for generating light by electrical pumping or optical pumping. The light-generating structure can for instance be bonded on top of the wafer (although there are likely interface layers in-between). The bonding can use molecular bonding or a layer of polymer or SiO₂ or, still, a bilayer of Al₂O₃ and SiO₂ or a combination thereof. However, using a bilayer of Al₂O₃ and SiO₂ is preferred because SiO₂ is a standard material in CMOS processes and Al₂O₃ can improve the bonding energy. Note that “on top of” means above (or below) and not necessarily “in direct contact with”, as consistently assumed in the art. Accordingly, if layer a of material A is “on top of” layer b of material B, then there is at least a partial overlap between layers a and b.

At least two light couplers 75, 76 are further provided, which are arranged such that at least part of the light-generating structure is between the light couplers. These couplers are, each configured for coupling light between the light-generating structure and the waveguide portions. Thus, they allow the light generated in the light-generating structure to be transferred to the waveguide portions 71, 72. As explained later in detail, the light couplers 75, 76 can for instance be provided in the waveguide portions 71, 72 and/or in the light-generating structure. I.e., the couplers can be obtained, for example, by patterning: (i) the photonic circuit's waveguide portions; (ii) the light-generating structure (e.g., III-V materials); or (iii) both the waveguide portions and the light-generating structure. The light couplers can notably be placed on top of a surface of a layer contiguous with the wafer or a surface of the wafer itself. Preferably, the couplers 75, 76 are shaped and placed such as to enable adiabatic coupling of the light between the light-generating structure and the waveguide portion (adiabatic meaning no substantial loss and no substantial back reflection).

Finally, the device 100 includes a reflector 90 arranged so as to reflect light propagating along said same direction back to a center of the light-generating structure. Importantly, the device 100 of the embodiment of FIG. 2 does not include, in embodiments, any other reflector on the other side of the light-generating structure, i.e., there is no additional reflector opposite to the partial reflector 90 with respect to the light-generating structure that could possibly reflect the light back to the center of the light-generating structure. In other words, the partial reflector 90 is asymmetrically arranged (and configured) with respect to the center of the light-generating structure, e.g., on one side only of the light-generating structure. Still, the partial reflector 90 could in fact be part of the light-generating structure, since its function is to reflect part of the generated light back to the center of the light-generating structure, from one side only. As the skilled person knows, a reflector will never reflect 100% of the light (the “partial reflector” is therefore simply referred to as a “reflector” in the following). It is here precisely relied on this property, in embodiments, to measure the optical gain, as to be explained later. The present photonic circuit devices can, in principle, be embodied with any reflector that only partly reflects light. Preferably, the reflector 90 should reflect between 10 and 90% of the light hitting it. A more preferred range is between 40 and 60% (e.g., a 50% reflection), which in practice allows to achieve better suited asymmetries of light power in each waveguide 71, 72, for measurement purposes. Note that more than one reflector 90 could be present on one side of the center. Also, in this description, “light” must be understood as “electromagnetic radiation”, i.e., it does not necessarily restrict to visible light, notwithstanding some applications cited herein. It is for instance common in the present technical field to speak of “infrared light”.

Most conveniently, the reflector 90 is arranged in the waveguide portion 72, as seen in FIG. 2. It could, in variants, be arranged at an end of the light-generating structure, close to the coupler 76, so as to intercept the optical path and reflect light back to the center of the light-generating structure. Even, the reflector 90 is preferably the only reflector that interacts with light generated by the light-generating structure, in the optical path defined by the direction along which the waveguide portions 71, 72 are aligned (besides additional couplers that are discussed below).

To obtain an efficient gain measurement structure, the light couplers 75, 76 can be provided as longitudinal couplers, i.e., longitudinally extending along the direction of extension of the waveguide portions 71, 72. This direction corresponds to the main direction of propagation of light in the couplers and the waveguide portions (light can propagate both ways along said direction). Using longitudinal light couplers 75, 76 is preferred as they more easily enable adiabatic coupling between the waveguide portions and the light-generating structure.

The light couplers 75, 76 can for instance include, each, at least one tapered portion 752; 762, where a tapered portion terminates a waveguide portion 71, 72 or is connected to the light-generating structure. The tapered portions can have an essentially parabolic shape, i.e., the lateral edges of the tapered portions are parabolic, and more generally can be nonlinear. A suitable design of the tapered portions can allow a smoother transformation of the optical mode, ensuring minimal scattering to the unwanted modes and shorter length of the tapered section. Further investigations on this matter have shown that, in some embodiments, a parabolic shape is actually not the most optimal geometry. Still, it can be regarded as an approximation to the optimal geometry, and at least as a better approximation than linear tapers.

Nonlinear tapers can be obtained using a single non-linear taper section or multiple taper sections, e.g., a linear section, followed by a non-linear for example parabolic section, itself followed by a linear section, etc. Preferred designs of the taper depend on the coupling efficiency target, geometry and refractive indices of the waveguides, and the size limitations. Depending on the available fabrication techniques, it can be more practical to approximate a non-linear taper portion by multiple successive linear sub-portions.

The conditions for achieving adiabatic light coupling between tapers were largely explored in the past. Analytical formulas describing tapers having optimal designs can be found in the literature. However, optimal taper parameters (adapted to the present context) can be determined from finite-difference time-domain (FDTD) simulations solving Maxwell's equations in time-domain.

Preferably, the reflector 90 is arranged at an end of a tapered portion of one of the waveguide portion, e.g., at the end of the tapered portion 762 (in that case it is integrated in the waveguide portion 72), as illustrated in FIG. 2. In variants, the reflector 90 can be located at an end of the tapered portion 761 (in that case it is integrated in the light-generating structure, at a periphery thereof). The closer the reflector to the periphery of the light-generating structure, the less losses and the more accurate the measurements. In terms of fabrication, however, it can be easier to fabricate the reflector in one of the waveguide portions, because the fabrication processes for waveguides are more mature and can resolve smaller features. Silicon is for instance preferred. Thus, providing the reflector at the end of a tapered portion 762 provides a satisfactory trade-off. More generally, the reflector can be located at the beginning of a coupler, e.g., in the light-generating structure or at the end of a coupler, e.g., coupler 76 in the figures, independently from the actual embodiment of the latter.

Each of the light couplers 75, 76 can include two tapered portions 751, 752; 761, 762. Consider the light coupler 75: it can have two tapered portions 751, 752 that are oppositely oriented and at least partly overlap. One of the tapered portions 752 terminates the waveguide portion 71, while the other tapered portion 751 is part of (or at least connects to) the light-generating structure, such as to efficiently optically couple the light-generating structure to the waveguide portions.

The device 100 can include additional light couplers (like coupler 81 of FIG. 2), directly integrated therein, to enable gain measurement. Namely, a light coupler can be included in each of the waveguide portions 71, 72, such that the reflector be located between one 76 of the light couplers and one of these additional couplers (one of these coupler [not shown] could be provided at the end of the waveguide portion 72). Each additional light coupler is preferably located at an end of a waveguide portion, i.e., opposite to that end that is the closest to the light couplers 75, 76. For example, the additional light couplers can be grating couplers, thereby making it possible to sense light vertically, i.e., to sense light emitted at an additional light coupler, perpendicularly to the surface including the waveguide portions. In variants, the additional light couplers could be configured for lateral measurement of emitted light. In other variants, the additional light couplers could be part of a sensing device (extrinsic couplers, not part of the device 100).

As said earlier, the photonic circuit is preferably a silicon photonic circuit. As illustrated in FIG. 2, the wafer can further include an electrical circuit 40 in addition to the photonic circuit. Said electrical circuit 40 can for instance be a complementary metal-oxide-semiconductor (CMOS) front end. More generally, the wafer can further include electronics.

Each of the waveguide portions 71, 72 can extend directly on a dielectric layer 20. The dielectric layer can be provided on top of the wafer. This dielectric layer 20 can be referred to as a buried oxide, e.g., SiO₂. It preferably has a thickness of more than 1 micrometer. The actual minimal thickness depends on the wavelength of the generated light: the light wavelength preferably used is, e.g., 1.3-1.55 micron. The dielectric layer provides a lower cladding for the waveguide portions, while providing a thermal and mechanical interface to the wafer. The dielectric layer 20 can thus advantageously be used to tune the mechanical and thermal properties of the device.

The waveguides 70-72 can be in contact with a bonding layer 50, the latter being typically a polymer, SiO₂ or Al₂O₃ (or any combination thereof). Again, a bilayer of Al₂O₃ and SiO₂ could serve as an interface. The waveguides 70, 71, 72 can be partly immersed in the bonding layer 50, as illustrated in FIG. 2, which makes it possible to tune the properties of the couplers 75, 76 by adapting the thickness of the bonding layer 50. They can nonetheless have one surface level with a surface of the bonding layer, which reduces variations of the coupling properties of the couplers 75, 76 induced by thickness variations of the bonding layer. If the bonding layer is flush with the surface of the photonic circuit, the latter can determine the height or the thickness of the bonding layer very accurately. In other variants, the device could be designed such that the waveguides 70, 71, 72 are partly surrounded (laterally) by air. This can enable easier bonding of gain material onto the wafer as light can be pushed out through the voids reducing the risk of air bubbles in and de-lamination of the bonded gain material.

The gain material can be bonded on top of the bonding layer 50. In variants, the light-generating structure can be arranged (directly or not) on top of the waveguide portions, using molecular bonding.

As explained in the previous section, the light-generating structure notably includes a bottom contact layer 32 (with a first contact pad 31, e.g., a metal contact) and an upper part 37, on top of the bottom contact layer 32 (with a second contact pad 38, e.g., a metal contact). It can further include an epitaxial layer stack (as shown in FIG. 1), which itself includes the n-doped semiconductor 32. Note that, owing to fabrication techniques used, a residual part of the n-doped semiconductor can reside in another layer, especially if patterning techniques are used to fabricate the epitaxial layer stack 34 (for example by lithography and etching).

The light-generating structure can be grown by molecular beam epitaxy (MBE) or by metal-organic chemical vapor deposition (MOCVD). In particular, the gain stack has the advantage, in embodiments, that the n-doped section is in proximity with the waveguide. This is particularly attractive as the p-doped section typically has a ten-times higher optical loss for the same doping level or concentration of dopants residing in the contact layers 32 and 37, respectively.

In variants, the gain stack can also include a tunnel junction enabling to terminate the device with a n-contact on either side, such that only one type of contact metal needs be applied, e.g., gold, tungsten, titanium, etc., it being reminded that, normally p- and n-doped regions use different types of metal to match the Fermi-levels and reduce the contact resistance.

In a possible example of implementation (for gain measurement applications), the photonic circuit includes two separated waveguides 71, 72 (which define, each, a waveguide portion as evoked above). The light couplers 75, 76 couple light between the light-generating structure and each of the two waveguides. To that aim, each light coupler 75, 76 includes two tapered portions, oppositely oriented and overlapping, as discussed above. Namely, one of the tapered portions 752, 762 forms an end of a waveguide portion, while the other tapered portions 751, 761 are connected to the light-generating structure, forming part thereof). The taper portions 751, 761 widen towards the center of the light-generating structure, while the tapered portions 752, 762 (the waveguides' tapers) narrow towards the center of the light-generating structure.

The above configuration can improve the adiabaticity of the coupling. Adiabaticity is achieved when the optical distribution is defined by the same eigenmode (i.e., supermode of the coupled waveguide system, e.g., fundamental even supermode, fundamental odd supermode) throughout the taper, with minimal scattering to other supermodes or radiation modes. Still, the loss is never perfectly zero. Adiabaticity is a relative term, as known in the art; a coupler is considered to be adiabatic when the loss is below a predefined, reasonable level, e.g. less than 15% (and often less than 10%).

The embodiment of FIG. 2 involves four tapered portions (in total). In variants, only two tapered portions (in total) can be provided, e.g., each forming part of the light-generating structure. In other variants, only two tapered portions are provided, each provided in a respective one of the waveguide portions.

The waveguide portions are not necessarily defined by respective, well defined waveguides. For example, a single waveguide could be provided, which defines said two waveguide portions, where the waveguide has a varying cross-section. For example, the latter can have a middle portion with a reduced width compared to outer portions, the later defining the two waveguide portions.

### 2.2 Technical Implementation Details and Fabrication

Possible methods of fabrication of the present photonic circuit devices are now discussed in detail, in reference to specific implementation of such devices.

The present photonic circuit devices can notably form on-chip lasing devices suitable for generating optical light using a special arrangement of the top contact. As discussed in detail in the previous sections, key advantages of such devices, in embodiments, are: the reduction of losses caused by metal contacts; the reduction of internal losses in the device; the formation of a fast low-threshold high-power laser; it offers full compatibility with CMOS processes; the accuracy in the alignment of the contact is not critical; and no additional lithography/patterning steps is needed.

Embodiments disclosed herein notably allow to improve the efficiency of thin light emitting devices, such as thin lasers, to reduce threshold current and increase output power. Since thin devices as contemplated herein have low electrical parasitics, embodiments disclosed herein enable directly modulated light sources.

Devices discussed herein include, in embodiments, an optically active gain section made of Germanium, GaAs, InP, InGaAs, InAlAs, InAlGaAs, InGaAsP, NAsP, GaSb, any of their alloy, or any other suitable compound semiconductor. This active gain section is contacted in a manner such that distortion of the optical field profile is minimized and optimized for reducing the absorption losses of both the metal contacts and the doping layers.

In a preferred fabrication method, the integration scheme retained is based on molecular bonding. A III-V based material is grown on a suitable substrate (III-V, Si, Ge, etc.) and optionally covered with a dielectric by molecular beam epitaxy, molecular vapor phase epitaxy, metal-organic chemical vapor deposition, atomic layer epitaxy, atomic layer deposition, sputtering or any other suitable thin film deposition technique. Then, this layer is bonded on top of the electronics wafer including the front end electronics and optics.

At this point, in embodiments, one of the following material is bonded: either a full III-V layer stack (serving as gain material), a seed-layer for successive re-growth bonded, or a III-V layer stack including both gain material and seed layer with appropriate etch-stops. The bonding is preferably performed on top of a dielectric layer residing on the CMOS wafer. In state-of-the-art CMOS processes, this layer typically is a silicon-dioxide layer, which has been polished by chemo-mechanical polishing (CMP) to provide a flat surface exhibiting low surface roughness. Since either wafers or wafer-scale bonded III-V based layers are used, the integration scheme lends itself for mass-fabrication and easy integration with current back-end fabrication schemes. During these back-end fabrication schemes, the metal contacts are applied and the devices are interconnected at wafer-scale level. When using specific (constrained) width ratios of the top contact and the laser device, a laser can be achieved that, in embodiments, has excellent performance in terms of compactness, high speed, low power consumption, high output power and high speed. This, on the contrary, is not possible with conventional contact architectures or designs.

In embodiments, a structure is designed such that an active material (e.g., a III-V-based material) is bonded on top of a wafer including a silicon photonics circuit. The silicon photonic circuit includes taper or coupler sections 75, 76 to transfer the light from the III-V region to the photonic circuit; and a reflector 90 embedded therein. Moreover, the silicon photonics circuit is residing on an oxide layer (buried oxide), which again is located on a silicon wafer thus forming a silicon-on-insulator (SOI) structure.

In other embodiments, the substrate gain includes a silicon photonic circuit, and in addition a complementary metal-oxide-semiconductor (CMOS) or bipolar (Bi) CMOS front-end-of-line (FEOL).

In still other embodiments, instead of two adiabatic coupling sections the waveguide between the reflectors 81, 90 is unstructured. In yet other embodiments, the wave-guiding section can have a varying width in order to tune the optical properties of the hybrid mode such as to obtain an improved overlap with the quantum well region embedded in the active III-V material.

The next fabrication step after fabrication of the silicon photonics and the front-end of line is typically the deposition of a layer suitable for bonding. The layer can be a polymer (for adhesive bonding) or (more preferably) a silicon dioxide or a silicon dioxide/alumina (Al2O3) bilayer. Still, that layer can also be made of alumina, hafnium dioxide, tantalum pent-oxide, barium titanate or strontium titanate. The layer can also be made of silicon nitride or silicon oxinitride. This layer can for instance resemble the first interlayer (also known as ILD1) between the electronic FEOL and the back-end-of-line (BEOL). The silicon dioxide layer can typically have a thickness between 10 and 2000 nm and a root mean square (rms) surface roughness of less than 0.5 nm. This surface roughness can be achieved by a dedicated deposition process. For instance, the silicon dioxide layer can be deposited by plasma enhanced chemical vapor deposition (PECVD) and subject to successive chemical-mechanical-polishing (CMP) steps.

After the oxide has been deposited and planarized, the III-V layer can be bonded on top of the wafer that acts as the host wafer for further processing.

The III-V material can notably be structured relative to the silicon waveguide or adiabatic coupling section and play the role of a bottom contact layer. Preferably and as said earlier, the bottom contact layer is made from highly n-doped indium phosphide (InP), although it can also be notably made from InGaAs or InAlAs.

After the structuring of the III-V gain layers is completed, contact pad can be fabricated (e.g., metal contacts, for simplicity and efficiency). The purpose of the contacts is to enable electrical pumping of the gain measurement device. The electrical contacts can notably be made of tungsten, titanium, titanium nitride, cobalt silicide, nickel silicide, poly silicon, gold, titanium, nickel, platinum, aluminum, copper or a combination thereof. Preferably though, the contacts are made of tungsten.

As described in the first section, applying metal contacts with a special geometry and shape results in a substantial improvement in laser performance. A preferred cross-section is shown in FIG. 1, but many other configurations can be contemplated, which fall under the scope of the appended claims.

### 2.3 Results

As present inventor has realized, it can be possible to apply, in embodiments, a laser contact width W_{L} such, that the quality factor Q exceeds that of the undisturbed cavity (without metal contact, i.e., with a contact width W_{c}=0).

A possible explanation is that the optical mode is forced to be zero at the metal interface (in case of an ideal conductor) and thus the position of the mode is moved away from the contact, and also from the p-doped region, which both introduce undesired absorption losses. The purpose of embodiments of the present invention is to specifically make use of this effect, whereby a contact (top or bottom) is formed such that the quality factor of the light-generating structure (with said contact) exceeds that of the undisturbed system (without said contact).

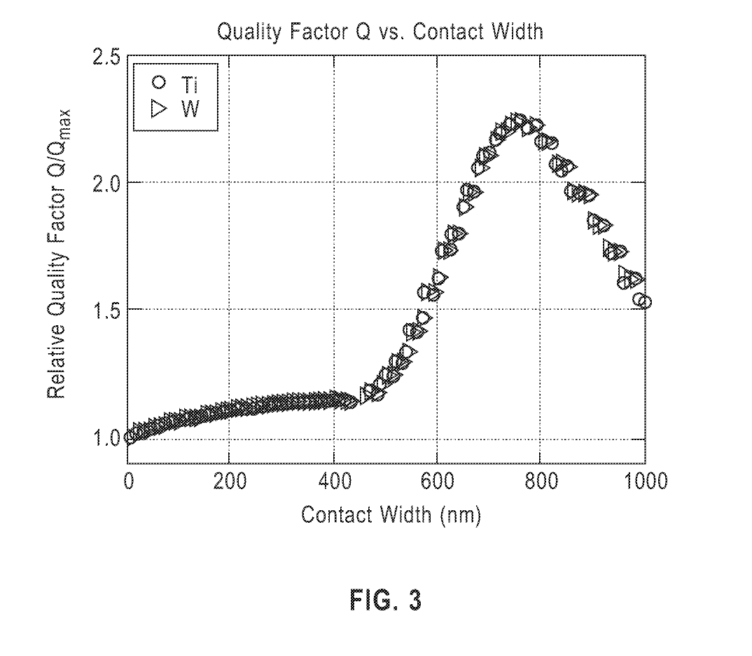

FIG. 3 shows the influence of the quality factor Q as a figure of merit of a laser cavity with a cross section as shown in FIG. 2, for different metal types (T, W) and a fixed laser width of W_{L}=400 nm, as a function of the contact width W_{c}. FIG. 3 displays the normalized quality factor Q as a function of the contact width W_{c}. The Q-Values are normalized to the quality factor Q₀ of the resonator without the top metal contact. As apparent from FIG. 3, the top metal contact can also increase the quality factor Q by reducing the contact losses. The metal contact forces a zero at the interface thus pushing the optical mode down and out of the highly absorptive p-region.

Note that, in contrast to a variety of scientific publications directed to “plasmonic lasers”, wherein a hybrid electron/photon (a Plasmon) is excited, and wherein the photons are TM polarized, one is here interested, in embodiments, in the “other” polarization. I.e., the target is TE-polarized light, which means that the electric field is extending in the wafer plane, whereas the magnetic field is perpendicular to the wafer plain, i.e., parallel to the wafer normal. This can be similar to the so-called Tamm-Plasmons effect reported in literature. However, in contrast to these optical modes, here the contact pad does not, in embodiments, have a wave-guiding function to generate a potential for the light confinement. Instead, in present embodiments, the contact pad 38 solely serves as a means to push the optical field away from the contact by forcing a zero electric field at the interface.

Thus, by accurately designing the top contact width and the laser width, it can be possible to push the light away from the contact and also the highly p-doped region underneath the contact, in order to substantially reduce the losses, which in turn allows to reduce the lasing threshold current and to improve the output power. Whereas in conventional laser designs the contact width is smaller than the laser width, here, in embodiments, a contact width larger than the laser ridge width is used, e.g., the laser width is W_{L}=400 nm, whereas the contact width is W_{c}=750 nm.

As can be seen from FIG. 3 (and as it was otherwise checked from various simulations), the concept is largely independent of the metal type. Metals exhibit a similar non-zero loss at the wavelengths of interest, i.e., in the infrared regime (around 1310 nm or 1550 nm).

Note, that for the plot of FIG. 3, a full Drude model was employed, which accurately describe the absorption of the respective metals.

Note that, in embodiments, different laser epitaxial materials can have different optimal contact ratios (for reducing the loss, and thereby improving the quality factor of the laser resonator).

To conclude, the proposed contact geometry can be employed to substantially improve the performance of integrated light sources, e.g., the laser sources required for silicon photonics, but also in other areas. The present embodiments do therefore not restrict to silicon photonics; they can notably be used for passive low-loss silica resonators, for bulk InP laser products, or still for GaAs-based devices including VCSELs.

In particular, the embodiments of present invention can provide a viable and convenient path towards fabricating high performance low-threshold lasers for on-chip applications and thus benefit to CMOS Integrated Silicon Nanophotonics technology.

While the present invention has been described with reference to a limited number of embodiments, variants and the accompanying drawings, it will be understood by those skilled in the art that various changes can be made and equivalents can be substituted without departing from the scope of the present invention. In particular, a feature (device-like or method-like) recited in a given embodiment, variant or shown in a drawing can be combined with or replace another feature in another embodiment, variant or drawing, to obtain a new combination of features (not explicitly recited herein) that nevertheless remains within the scope of the present invention, especially where such a new combination would provide an advantage recited in the present description and, this, notwithstanding the particular technical contexts in which the features constituting this new combination can have been described and provided that such a new combination makes sense for the one skilled in the art, in view of other elements described in the present application, such as advantages provided by the features described herein. Various combinations of the features described in respect of any of the above embodiments or variants can accordingly be contemplated, that remain within the scope of the appended claims. In addition, many minor modifications can be made to adapt a particular situation to the teachings of the present invention without departing from its scope. Therefore, it is intended that the present invention not be limited to the particular embodiments disclosed, but that the present invention will include all embodiments falling within the scope of the appended claims. In addition, many variants not explicitly touched above can be contemplated. For example other materials than those explicitly discussed can be contemplated. As another example, additional layers can be involved in the light-generating structure.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. A photonic circuit device, comprising:
a light-generating structure, comprising:
an n-doped semiconductor layer,
a p-doped semiconductor layer, and
an active gain section comprising layers stacked along a stacking direction, the active gain section arranged between the n-doped semiconductor layer and the p-doped semiconductor layer, the active gain section coupled in the photonic circuit device for generating light propagating along a given propagation direction; and
at least two electrical contact pads, including an n-contact electric pad and a p-contact electric pad, in electrical contact with the n-doped semiconductor layer and the p-doped semiconductor layer, respectively, where one of the electrical contact pads, at least, is in direct contact with the light-generating structure,
wherein a ratio of a width of said one of the electrical contact pads to the width of the active gain section is between 1.35 and 3.85, the widths of said one of the electrical contact pads and the width of the active gain section measured orthogonal to each of the stacking direction and said given propagation direction.

2. The device of claim 1, wherein said ratio is between 1.80 and 2.70.

3. The device of claim 1, wherein said one of the electrical contact pads is stacked onto the light-generating structure, along the stacking direction.

4. The device of claim 3, wherein said one of the electrical contact pads is centered with respect to the light-generating structure.

5. The device of claim 3, wherein said one of the electrical contact pads is cantilevered overhang on the light-generating structure.

6. The device of claim 1, wherein said one of the electrical contact pads that is in direct contact with the light-generating structure is the p-contact electric pad.

7. The device of claim 1, further comprising two separate confinement hetero structure layers on each side of the active gain section, and between the n-doped and p-doped semiconductor layers.

8. The device of claim 1, wherein the width of the active gain section is less than 10000 nm.

9. The device of claim 8, wherein the width of the active gain section is less than 1000 nm.

10. The device of claim 1, further comprising a substrate supporting the light-generating structure, which substrate otherwise comprises a photonic circuit.

11. The device of claim 1, wherein another one of the electrical contact pads is not stacked with the light-generating structure and is laterally offset from the light-generating structure, in the direction in which said widths are measured.

12. The device of claim 1, wherein the active gain section has a ring shape.

13. The device of any one of claims 1, wherein the active gain section comprises a stack of InAlGaAs layers of alternating thicknesses, and wherein each of the n-doped and p-doped semiconductor layers comprises InP.

14. The device of claim 13, wherein the light-generating structure further comprises two separate confinement heterostructure layers on each side of the active gain section, and between the n-doped and p-doped semiconductor layers, which confinement heterostructure layers comprise, each, InAlGaAs.

15. The device of claim 1 further comprising a CMOS device comprising having a front end of line and a back end of line, wherein the device is arranged between the front end of line and the back end of line of the CMOS device.
